(19) United States
(12) Patent Application Publication
(10) Pub. No.: US 2024/0333297 A1
(43) Pub. Date: Oct. 3, 2024

(54) SUCCESSIVE APPROXIMATION TYPE A/D CONVERTER

(71) Applicant: ROHM CO., LTD., Kyoto (JP)

(72) Inventor: Naohiro NOMURA, Kyoto (JP)

(21) Appl. No.: 18/612,301

(22) Filed: Mar. 21, 2024

(30) Foreign Application Priority Data
Mar. 28, 2023 (JP) 2023-052368

(51) Int. Cl. H03M 1/38

(52) U.S. Cl. CPC H03M 1/38

(57) ABSTRACT

A successive approximation type A/D converter includes: a capacitive D/A converter, and a buffer circuit configured to supply a reference voltage to the capacitive D/A converter, wherein the buffer circuit includes: a reference voltage source configured to generate a constant voltage, a first stage amplifier configured to amplify the constant voltage, an output buffer with a gain of 1 configured to receive a voltage according to an output voltage of the first stage amplifier, and a filter that is interposed between the first stage amplifier and the output buffer and acts on a signal directed from the output buffer to the first stage amplifier, and wherein a tail current of a differential amplifier of the output buffer is larger than a tail current of a differential amplifier of the first stage amplifier.

### CROSS-REFERENCE TO RELATED APPLICATION

The present invention claims priority under 35 U.S.C. § 119 Japanese Patent Application No. 2023-052368, filed on Mar. 28, 2023, the entire contents of which are incorporated herein by reference.

### TECHNICAL FIELD

The present disclosure relates to a successive approximation type A/D converter.

### BACKGROUND

A successive approximation register (SAR) is used as an analog/digital (A/D) converter (ADC) with medium resolution to high resolution (for example, 8 bits or more). The SAR-ADC samples/holds an input voltage and compares it with a first threshold voltage. Then, a second threshold voltage is determined according to the comparison result, and the comparison is performed again. By repeating this operation, an analog voltage is converted into a digital signal by binary search.

### BRIEF DESCRIPTION OF DRAWINGS

The accompanying drawings, which are incorporated in and constitute a part of the specification, illustrate embodiments of the present disclosure.

FIG. 1 is a block diagram showing a basic configuration of a successive approximation type A/D converter according to an embodiment.

FIG. 2 is a circuit diagram of a buffer circuit.

FIG. 3 is a circuit diagram of a buffer circuit according to one Example.

FIG. 4 is a circuit diagram of a buffer circuit according to a comparative technique.

FIG. 5 is an operation waveform diagram (simulation results) of the buffer circuit of FIG. 4.

FIG. 6 is an operation waveform diagram (simulation results) of the buffer circuit of FIG. 3.

FIG. 7 is a circuit diagram of a buffer circuit according to Modification 1.

FIG. 8 is a circuit diagram of a buffer circuit according to Modification 2.

FIG. 9 is a diagram showing frequency characteristics of a first stage amplifier in each of the buffer circuit of FIG. 3 and the buffer circuit of FIG. 8.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview of Embodiments

An overview of some exemplary embodiments of the present disclosure is described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience, “an embodiment” may be used to refer to one embodiment (example or modification) or a plurality of embodiments (examples or modifications) disclosed herein.

A successive approximation type A/D converter according to one embodiment includes a capacitive D/A converter and a buffer circuit that supplies a reference voltage to the capacitive D/A converter. The buffer circuit includes a reference voltage source that generates a constant voltage, a first stage amplifier that amplifies the constant voltage, an output buffer that receives a voltage according to an output voltage of the first stage amplifier, and a filter that is interposed between the first stage amplifier and the output buffer and acts on a signal directed from the output buffer to the first stage amplifier. A tail current of a differential amplifier of the output buffer is larger than a tail current of a differential amplifier of the first stage amplifier.

According to this configuration, by configuring the buffer circuit in two stages and interposing the filter between the two stages to prevent signal propagation in the opposite direction, it is possible to prevent oscillation of the reference voltage from being transmitted to the first stage amplifier when the capacitive DAC switches. As a result, it is possible to suppress fluctuation in the constant voltage generated by the reference voltage source and stabilize the reference voltage which is the output of the buffer circuit.

In one embodiment, the filter may be of an RCR type.

In one embodiment, the filter may be of an RC type.

In one embodiment, the first stage amplifier may be a non-inverting amplifier.

In one embodiment, the output buffer may be a voltage follower.

In one embodiment, the first stage amplifier may be a voltage follower.

In one embodiment, a tail current source of the first stage amplifier and a tail current source of the output buffer may be biased by a common transistor.

In one embodiment, the successive approximation type A/D converter may be monolithically integrated on one semiconductor substrate. The term “monolithically integrated” is intended to include both a case where all circuit elements are formed on a semiconductor substrate and a case where main elements of the circuit are integrated on the semiconductor substrate. In addition, some resistors, capacitors, and the like for adjustment of a circuit constant may be provided outside the semiconductor substrate. By integrating the circuit on one chip, it is possible to reduce the circuit area and keep the characteristics of the circuit elements uniform.

### Embodiments

In the present disclosure, “a state where a member A is connected to a member B” includes not only a case where the member A and the member B are physically and directly connected, but also a case where the member A and the member B are indirectly connected through any other member that does not substantially affect an electrical connection state between the members A and B or does not impair functions and effects achieved by combinations of the members A and B.

Similarly, “a state where a member C is installed between a member A and a member B” includes not only a case where the member A and the member C or the member B and the member C are directly connected, but also a case where the member A and the member C or the member B and the member C are indirectly connected through any other member that does not substantially affect an electrical connection state between the members A and C or the members B and C or does not impair functions and effects achieved by combinations of the members A and C or the members B and C.

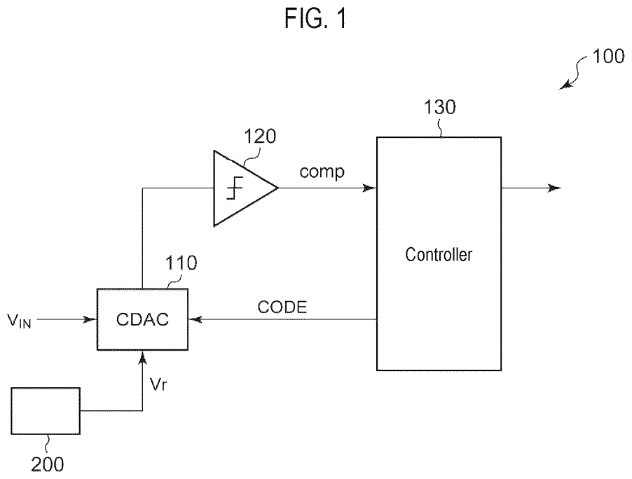

FIG. 1 is a block diagram showing a basic configuration of a successive approximation type A/D converter (SAR-ADC) 100 according to an embodiment. The SAR-ADC 100 is monolithically integrated on one semiconductor substrate. The SAR-ADC 100 may be a dedicated chip for an A/D converter, or may be integrated into an IC (Integrated Circuit) having other functions. Alternatively, the SAR-ADC 100 may have a digital part and an analog part made up of separate chips.

The SAR-ADC 100 includes a capacitive DAC 110, a comparator 120, and a controller 130. The capacitive DAC 110 samples an input voltage V_{IN}. Further, the capacitive DAC 110 generates a threshold voltage V_{THk} according to a control code CODEk where k indicates a cycle of successive approximation processing. The comparator 120 generates a comparison signal comp indicating a magnitude relationship between the input voltage V_{IN} and the threshold voltage V_{THk} based on the state of the capacitive DAC 110. For example, the comparison signal comp is H (high) when the input signal V_{IN} is larger than the threshold voltage V_{THk}, and is L (low) when the input signal V_{IN} is smaller than the threshold voltage V_{THk}. The controller 130 determines a control code CODEk+1 for the next cycle k+1 based on the output comp of the comparator 120. The SAR-ADC 100 repeats this operation.

A reference voltage Vr is supplied to the capacitive DAC 110 from a buffer circuit 200. The capacitive DAC 110 charges an internal capacitor using the reference voltage Vr.

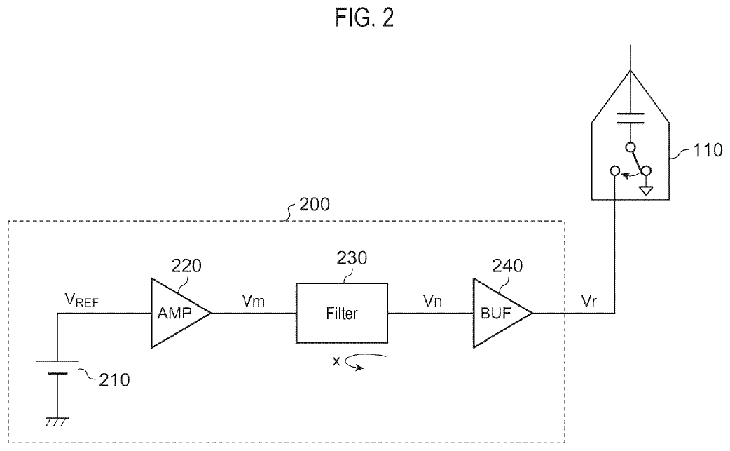

FIG. 2 is a circuit diagram of the buffer circuit 200. The buffer circuit 200 includes a reference voltage source 210, a first stage amplifier 220, a filter 230, and an output buffer 240. The reference voltage source 210 generates a reference voltage V_{REF}. The reference voltage source 210 may be a band gap reference circuit or other constant voltage source, although not limited to this.

The first stage amplifier 220 amplifies the reference voltage V_{REF} with a gain g. The gain g may be determined based on the reference voltage V_{REF} and the reference voltage Vr to be supplied to the capacitive DAC 110.

g=Vr/V_{REF}

An output voltage Vm of the first stage amplifier 220 is expressed by the following equation.

Vm=g×V_{REF}

The output buffer 240 receives a voltage Vn based on the output voltage Vm of the first stage amplifier 220. The output buffer 240 has a gain of 1 and its role is impedance conversion. The voltage level of the output voltage Vr of the output buffer 240 is equal to the voltage level of the output voltage Vm of the first stage amplifier 220.

The filter 230 is interposed between the first stage amplifier 220 and the output buffer 240. However, the filter 230 is different from a general filter in that its function is to block a signal from passing from the output buffer 240 to the first stage amplifier 220.

The output buffer 240 is configured to operate at a higher speed than the first stage amplifier 220. Specifically, both the output buffer 240 and the first stage amplifier 220 are configured using an operational amplifier, and a differential amplifier is provided at the first stage of the operational amplifier. A tail current (bias current) of the differential amplifier of the operational amplifier of the output buffer 240 is larger than a tail current of the first stage differential amplifier of the operational amplifier of the first stage amplifier 220.

The above is a configuration of the buffer circuit 200.

The present disclosure covers various devices and methods that can be understood as the block diagrams or circuit diagrams of FIGS. 1 and 2 or derived from the above description, and is not limited to a specific configuration. More specific configuration examples and examples will be described below, not to narrow the scope of the present disclosure, but to help understand and clarify the essence and operation of the present disclosure and the present invention.

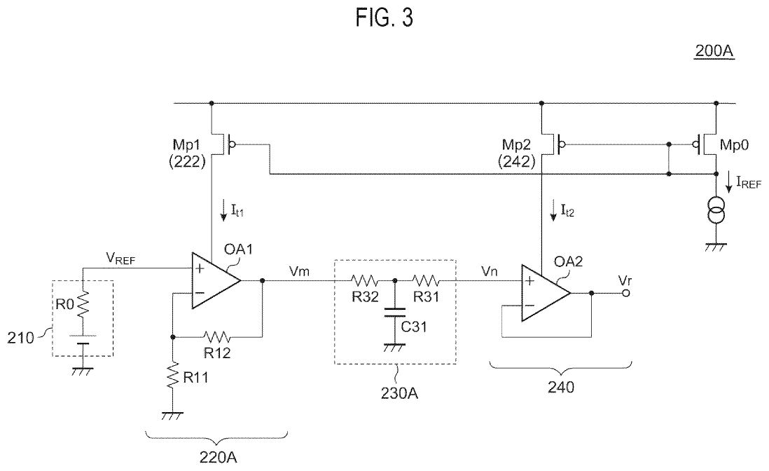

FIG. 3 is a circuit diagram of a buffer circuit 200A according to one Example. A first stage amplifier 220A of the buffer circuit 200A is a non-inverting amplifier and includes an operational amplifier OA1 and resistors R11 and R12. The gain g of the first stage amplifier 220A is g=(R11+R12)/R11. A transistor Mp1 represents a tail current source 222 of a first stage differential amplifier of the operational amplifier OA1 of the first stage amplifier 220A.

On the other hand, the output buffer 240 is a voltage follower circuit, and its gain is 1. The output buffer 240 includes an operational amplifier OA2, and the inverting input terminal and output of the operational amplifier OA2 are connected to each other. A transistor Mp2 represents a tail current source 242 of the first stage differential amplifier of the operational amplifier OA2.

A current It2 generated by the tail current source 242 and a current It1 generated by the tail current source 222 satisfy the following relationship.

It2>It1

A transistor Mp0 is connected to the transistors Mp1 and Mp2. The transistors Mp0, Mp1, and Mp2 form a current mirror circuit with the transistor Mp0 as an input and the transistors Mp1 and Mp2 as an output. A reference current I_{REF} is supplied to the transistor Mp0. That is, the transistors Mp1 and Mp2 are biased by the common transistor Mp0, and the tail currents It1 and It2 proportional to the reference current I_{REF} flow through the transistors Mp1 and Mp2. The size (gate width/gate length W/L) of the transistor Mp2 is designed to be larger than the size of the transistor Mp1, so that It2>It1.

A filter 230A includes a resistor R31 and a capacitor C31. As described above, the function of the filter 230A is to block a signal from passing from the output buffer 240 to the first stage amplifier 220. This function is performed by an RC filter consisting of the resistor R31 and the capacitor C31.

The filter 230A further includes a resistor R32. When viewed from the first stage amplifier 220A, the capacitor C31 becomes a capacitive load. If the capacitor C31 is directly connected to the output of the first stage amplifier 220A, the stability of the first stage amplifier 220A will be reduced, making it difficult to design the first stage amplifier 220A. The resistor R32 serves as a separation resistor, thereby increasing the stability of the first stage amplifier 220A. Further, since the resistor R32 and the capacitor C31 form a low-pass filter, it is also possible to remove noise signals directed from the first stage amplifier 220A to the filter 230A.

The above is a configuration of the buffer circuit 200A.

The advantages of the buffer circuit 200A become clear when compared with a comparative technique. Therefore, a configuration of the comparative technique and the problems that occur therein will be described.

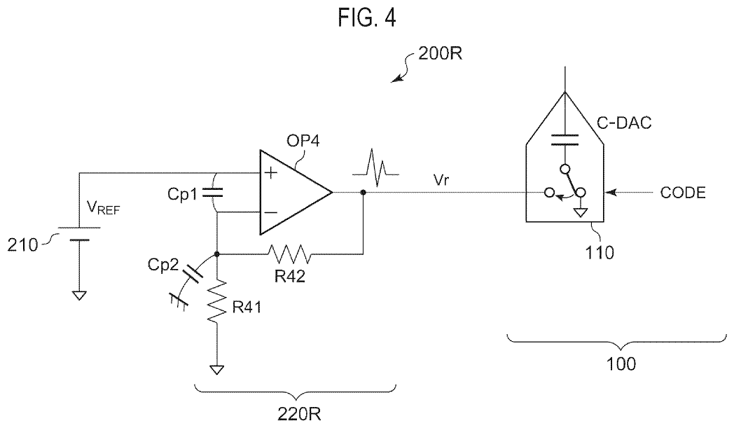

FIG. 4 is a circuit diagram of a buffer circuit 200R according to the comparative technique. The buffer circuit 200R includes a reference voltage source 210 and a non-inverting amplifier 220R. The non-inverting amplifier 220R includes an operational amplifier OA4 and resistors R41 and R42 and has a gain of g=(R41+R42)/R41. The output voltage of the non-inverting amplifier 220R is supplied as the reference voltage Vr to the capacitive DAC 110.

When the capacitive DAC 110 of the SAR-ADC 100 switches in accordance with a control code CODE, it oscillates the potential Vr of the output node of the non-inverting amplifier 220R. This oscillation (noise signal) goes around to the inverting input terminal (summing node) of the operational amplifier OP4 via the resistor R42. Here, since the resistor R42 forms a low-pass filter together with a capacitor Cp2, the signal that goes around to the inverting input terminal is delayed. This results in slowing down the settling of the inverting input terminal and slowing down the settling of the oscillating output.

Further, a parasitic capacitance Cp1 also exists between the inverting input terminal and the non-inverting input terminal of the operational amplifier OP4. A noise signal propagates to the output node of the reference voltage source 210 via this parasitic capacitance Cp1. Here, the reference voltage source 210 is a band gap reference circuit or the like, and is not an ideal voltage source with zero output impedance, but has an output impedance that cannot be ignored. Therefore, the noise signal changes the reference voltage V_{REF}. When the reference voltage V_{REF} is changed, the output voltage Vr of the non-inverting amplifier 220R is also changed. Further, if the reference voltage source 210 is shared not only with the non-inverting amplifier 220R but also with other circuit blocks, a change in the reference voltage V_{REF} will degrade the performance of the entire circuit.

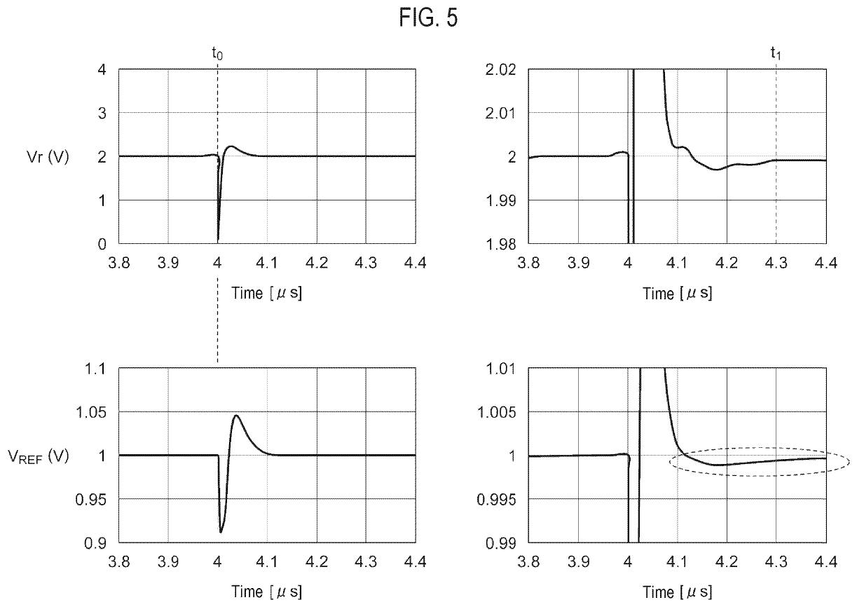

FIG. 5 is an operation waveform diagram (simulation results) of the buffer circuit 200R of FIG. 4. The upper stage shows the output voltage Vr, and the lower stage shows the reference voltage V_{REF}. In each figure, the waveform on the right is an enlarged version of the waveform on the left in the voltage axis direction.

The conditions for the simulation are as follows:
Reference voltage V_{REF}=1 V
Gain g=2
Reference voltage Vr=2 V

In the simulation, at time t₀, the code CODE of the capacitive DAC 110 is changed by an amount corresponding to a full code from 0 V to 2 V in a voltage generated by the capacitive DAC 110. Further, the output impedance of the reference voltage source 210 is set to 1 MΩ.

When switching occurs in the capacitive DAC 110, the output voltage Vr of the buffer circuit 200R oscillates, but it appears to settle in about 0.3 μs. However, looking at the enlarged waveform at the lower stage, the output voltage Vr converges to a voltage lower than the target level of 2 V, and an error occurs.

Referring to the waveform of the reference voltage V_{REF} in the lower stage, it can be seen that after switching, the reference voltage V_{REF}, that is, the input voltage of the non-inverting amplifier 220R, is at a voltage level lower than 1 V. This is due to the influence of going-around of noise via the resistor R42 and the parasitic capacitance Cp1. As the reference voltage V_{REF} shifts, it is amplified and appears as an error in the output voltage Vr.

In this way, in the comparative technique, the reference voltage Vr has an error each time the capacitive DAC 110 switches. Therefore, the conversion accuracy of the SAR-ADC 100 decreases. Alternatively, it is necessary to wait until the reference voltage Vr returns to a normal voltage level (2 V in this example) each time switching is performed, which reduces the operating speed of the SAR-ADC 100.

Further, when the reference voltage V_{REF} is shared with other circuit blocks, an error in the reference voltage V_{REF} propagates to the other circuit blocks, degrading the performance of the SAR-ADC 100.

The above are the problems that occur in the comparative technique. Return to the Example.

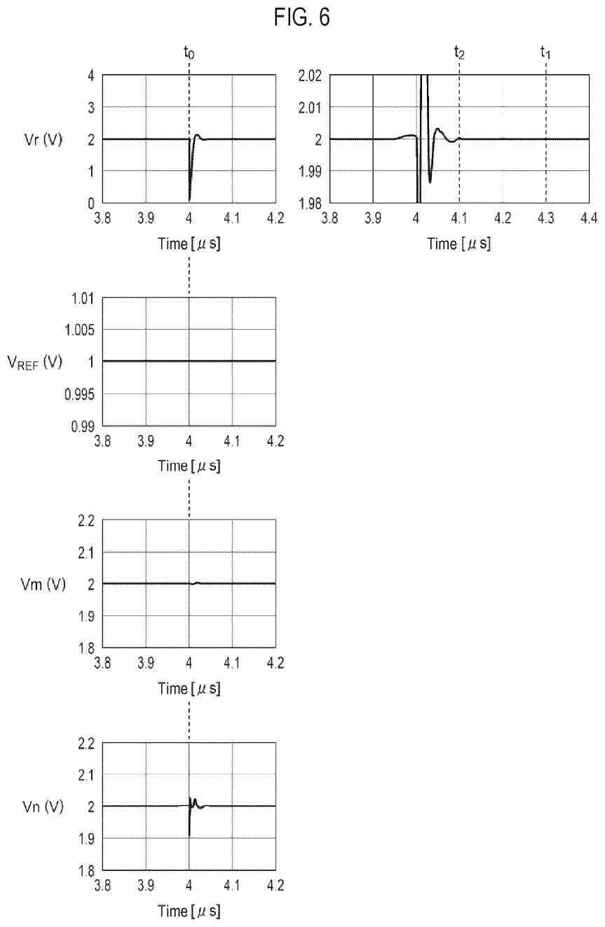

FIG. 6 is an operational waveform diagram (simulation results) of the buffer circuit 200A of FIG. 3. The simulation conditions are the same as those in FIG. 5. In FIG. 6, the output voltage Vr of the output buffer 240, the reference voltage V_{REF}, the output voltage Vm of the first stage amplifier 220A, and the input voltage Vn of the first stage amplifier 220 are shown in order from the top.

As can be seen from these simulation results, in the Example, the reference voltage V_{REF} is kept at 1 V. Further, the output voltage Vr of the buffer circuit 200A converges to 0.1 μs (time t₂), and its settling time can be shorter than 0.3 μs (time t₁) of the comparative technique. Furthermore, the voltage level after settling is 2 V, which shows that the error can be reduced as compared to the comparative technique.

The above-described embodiments are merely examples, and those skilled in the art will understand that various modifications can be made to the combinations of their constituent elements and processing processes. Hereinafter, such modifications will be described.

### Modification 1

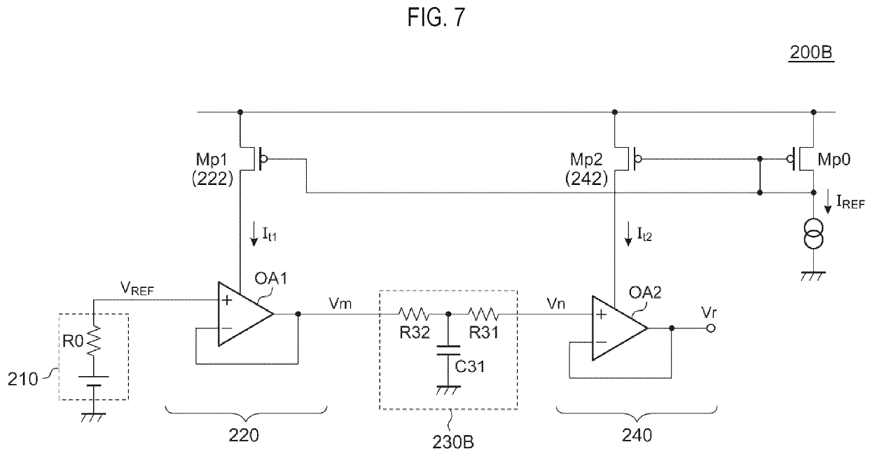

FIG. 7 is a circuit diagram of a buffer circuit 200B according to Modification 1. In this buffer circuit 200B, the first stage amplifier 220B is a voltage follower, and the rest is the same as the buffer circuit 200A in FIG. 3. This configuration also provides the same effects as the buffer circuit 200A of FIG. 3.

### Modification 2

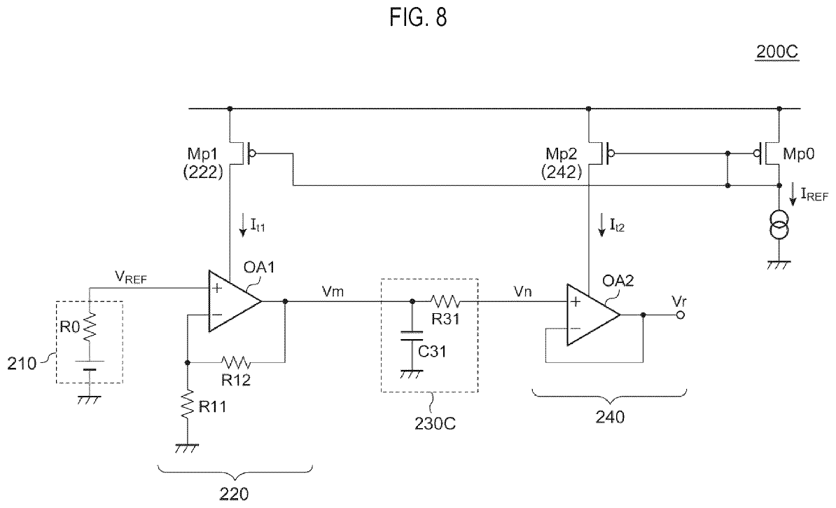

FIG. 8 is a circuit diagram of a buffer circuit 200C according to Modification 2. In this buffer circuit 200C, the configuration of a filter 230C is different from that of the filter 230A in FIG. 3 in that, specifically, the resistor R32 is omitted. This configuration also provides the same effects as the buffer circuit 200A of FIG. 3. Since there is no resistor R32, there is an effect of reducing the circuit area.

However, since a capacitor C31 of the filter 230C is directly connected to the output of the first stage amplifier 220, this is disadvantageous from the viewpoint of stability.

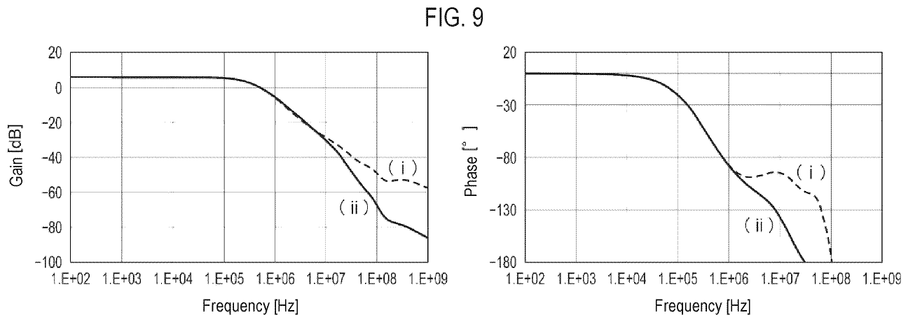

FIG. 9 is a diagram showing frequency characteristics of the first stage amplifier 220 in each of the buffer circuit 200A of FIG. 3 and the buffer circuit 200C of FIG. 8. In FIG. 9, (i) shows the frequency characteristics of the buffer circuit 200C without the resistor R31, and (ii) shows the frequency characteristics of the buffer circuit 200A with the resistor R31. In the configuration without the resistor R31, a phase is rapidly rotated by the second pole in the high frequency range. Therefore, depending on the configuration of the operational amplifier, the circuit becomes unstable. On the other hand, by inserting the resistor R31, the capacitor C31 is separated, so that the frequency characteristics can be improved.

### Supplementary Notes

The following techniques are disclosed in the present disclosure.

### Supplementary Note 1

A successive approximation type A/D converter including:
a capacitive D/A converter; and
a buffer circuit configured to supply a reference voltage to the capacitive D/A converter,
wherein the buffer circuit includes:
   a reference voltage source configured to generate a constant voltage;
   a first stage amplifier configured to amplify the constant voltage;
   an output buffer with a gain of 1 configured to receive a voltage according to an output voltage of the first stage amplifier; and
   a filter that is interposed between the first stage amplifier and the output buffer and acts on a signal directed from the output buffer to the first stage amplifier, and
wherein a tail current of a differential amplifier of the output buffer is larger than a tail current of a differential amplifier of the first stage amplifier.

### Supplementary Note 2

The successive approximation type A/D converter of Supplementary Note 1, wherein the filter also acts on a signal directed from the first stage amplifier to the output buffer.

### Supplementary Note 3

The successive approximation type A/D of Supplementary Note 2, wherein the filter is of an RCR type.

### Supplementary Note 4

The successive approximation type A/D converter of Supplementary Note 1, wherein the filter is of an RC type.

### Supplementary Note 5

The successive approximation type A/D converter of any one of Supplementary Notes 1 to 4, wherein the first stage amplifier is a non-inverting amplifier.

### Supplementary Note 6

The successive approximation type A/D converter of any one of Supplementary Notes 1 to 4, wherein the first stage amplifier is a voltage follower.

### Supplementary Note 7

The successive approximation type A/D converter of any one of Supplementary Notes 1 to 6, wherein the output buffer is a voltage follower.

### Supplementary Note 8

The successive approximation type A/D converter of any one of Supplementary Notes 1 to 7, wherein a tail current source of the first stage amplifier and a tail current source of the output buffer are biased by a common transistor.

It will be understood by those skilled in the art that the embodiments are illustrative and there are various modifications to the combinations of the constituent elements and processing processes and that such modifications are also included in the scope of the present disclosure or the present invention.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A successive approximation type A/D converter comprising:
a capacitive D/A converter; and
a buffer circuit configured to supply a reference voltage to the capacitive D/A converter,
wherein the buffer circuit includes:
a reference voltage source configured to generate a constant voltage;
a first stage amplifier configured to amplify the constant voltage;
an output buffer with a gain of 1 configured to receive a voltage according to an output voltage of the first stage amplifier; and
a filter that is interposed between the first stage amplifier and the output buffer and acts on a signal directed from the output buffer to the first stage amplifier, and
wherein a tail current of a differential amplifier of the output buffer is larger than a tail current of a differential amplifier of the first stage amplifier.

2. The successive approximation type A/D converter of claim 1, wherein the filter also acts on a signal directed from the first stage amplifier to the output buffer.

3. The successive approximation type A/D converter of claim 2, wherein the filter is of an RCR type.

4. The successive approximation type A/D converter of claim 1, wherein the filter is of an RC type.

5. The successive approximation type A/D converter of claim 1, wherein the first stage amplifier is a non-inverting amplifier.

6. The successive approximation type A/D converter of claim 1, wherein the first stage amplifier is a voltage follower.

7. The successive approximation type A/D converter of claim 1, wherein the output buffer is a voltage follower.

8. The successive approximation type A/D converter of claim 1, wherein a tail current source of the first stage amplifier and a tail current source of the output buffer are biased by a common transistor.
